(19) United States
(12) Patent Application Publication
(10) Pub. No.: US 2018/0348586 A1
(43) Pub. Date: Dec. 6, 2018

(54) ARRAY SUBSTRATE AND REPAIR METHOD, DISPLAY PANEL AND DISPLAY APPARATUS

(71) Applicants: BOE TECHNOLOGY GROUP CO., LTD., Beijing (CN); HEFEI XINSHENG OPTOELECTRONICS TECHNOLOGY CO., LTD, Hefei (CN)

(72) Inventors: Junjie LI, Beijing (CN); Fei TENG, Beijing (CN); Guoquan LIU, Beijing (CN)

(73) Assignees: BOE TECHNOLOGY GROUP CO., LTD., Beijing (CN); HEFEI XINSHENG OPTOELECTRONICS TECHNOLOGY CO., LTD ., Hefei (CN)

(21) Appl. No.: 15/519,551

(22) PCT Filed: Jul. 1, 2016
(86) PCT No.: PCT/CN2016/088173

§ 371 Date: Apr. 16, 2017

(30) Foreign Application Priority Data
Feb. 15, 2016 (CN) 201610086241.1

(51) Int. Cl. G02F 1/1362; H01L 21/66; H01L 27/12; H01L 21/768

(52) U.S. Cl. CPC G02F 1/136259; H01L 22/22; H01L 27/1244; G02F 1/134363; G02F 2001/136263; G02F 2001/136272; H01L 21/76894

(57) ABSTRACT

The present disclosure provides an array substrate and and a repair method thereof. The array substrate comprises a first metal layer including a signal line; a first repair layer; and a first insulating layer. The first insulating layer is disposed between, and provides insulation between, the first metal layer and the first repair layer, and it is configured to be penetrable to allow the first repair layer to electrically connect the signal line to thereby repair connection weakness of the signal line. The first repair layer can comprise a first repair line, which is disposed over and along the signal line and is configured to be able to electrically connect two ends of a weak connection portion of the signal line through vias penetrating the first insulating layer.

### CROSS-REFERENCE TO RELATED APPLICATION

The present application claims priority to Chinese Patent Application No. 201610086241.1 filed on Feb. 15, 2016, the disclosure of which is hereby incorporated by reference in its entirety.

### TECHNICAL FIELD

The present disclosure relates to display technologies, and more specifically to an array substrate and its repair method, a display panel and a display apparatus.

### BACKGROUND

Flat-panel display apparatuses, such as Liquid Crystal Display (LCD) apparatus, Plasma Display Panel (PDP), Organic Light-Emitting Diode (OLED) display apparatuses, etc., have been developed rapidly due to their advantages over traditional displays, such as light weight, small size, and low power consumption.

### SUMMARY

The inventors of the present disclosure have recognized that when repairing data line open circuits employing bridging with tungsten powder, and laser cutting or scraping, the second transparent electrode layer can be easily damaged, causing decreased display quality or display abnormalities of peripheral pixels.

In one aspect, the present disclosure provides an array substrate.

The array substrate comprises a first metal layer including a signal line, a first repair layer, and a first insulating layer. The first insulating layer is disposed between, and provides insulation between, the first metal layer and the first repair layer, and it is configured to be penetrable to allow the first repair layer to electrically connect the signal line to thereby repair connection weakness of the signal line.

In some embodiments, the first repair layer comprises a first repair line, which is disposed over and along the signal line and is configured to be able to electrically connect two ends of a weak connection portion of the signal line through vias penetrating the first insulating layer.

In some embodiments, the array substrate further includes a substrate, and the projection of the first repair line on the substrate overlaps with the projection of the signal line on the substrate in a longitudinal direction.

The signal line in the first metal layer can comprise a data line, but can also comprise some other type of the signal line.

The first repair line can be an integral wire, but in some preferred embodiments, the first repair line can comprise a plurality of first segments, which are electrically disconnected from one another.

The array substrate can further comprise a second repair layer including a second repair line. The second repair line is insulated from, and disposed over and along, the data line. The projection of the second repair line on the substrate overlaps with the projection of the data line on the substrate in a longitudinal direction; and the second repair line can also include a plurality of second segments, which are electrically disconnected from one another. The plurality of first segments of the first repair line and the plurality of second segments of the second repair line are configured such that at least one of one corresponding first segment of the first repair line or one corresponding second segment of the second repair line is able to electrically connect the two ends of the weak connection portion of the data line through one or more vias.

In some of the embodiments as described above, tach one of the plurality of first segments of the first repair line can be staggered with, and partially overlapped at ends with, one of the plurality of second segments of the second repair line.

In some embodiments, the first repair layer and the second repair layer can be a pixel electrode layer and a common electrode layer, or can be a common electrode layer or a pixel electrode layer.

In embodiments where the first repair layer is a pixel electrode layer, and the second repair layer is a common electrode layer, the pixel electrode layer can also include a plurality of pixel electrodes, which are insulated from the first repair line, and the common electrode layer can include a plurality of common electrodes, which are insulated from the second repair line.

The array substrate can further comprise a second metal layer, which includes a plurality of gate lines. In such an embodiment, the second repair layer, the second metal layer, the first metal layer, and the first repair layer can be sequentially disposed on the substrate; and the plurality of gate lines in the second metal layer are insulated from the second repair line in the second repair layer.

In some embodiments, the array substrate can further include a second insulating layer, which is disposed between, and configured to insulate, the second metal layer and the first metal layer.

In a second aspect, the present disclosure provides a display panel, which includes the array substrate according to any of the embodiments as described above.

In a third aspect, the present disclosure provides a display apparatus, which includes the display panel as described above.

In a fourth aspect, the present disclosure provides a method for repairing the array substrate as described above. The method includes a step of connecting the two ends of the weak connection portion of the signal line with vias through the first repair line.

In some embodiments of the method, the step of connecting the two ends of the weak connection portion of the signal line with vias through the first repair line is performed by welding the first repair line with the two ends of the weak connection portion of the signal line through vias.

In some embodiments of the method, the first repair line can include a plurality of first segments, which are electrically disconnected from one another; and the step of connecting the two ends of the weak connection portion of the signal line with vias through the first repair line can be performed by welding one of the plurality of first segments of the first repair line with the two ends of the weak connection portion of the signal line through vias.

In some embodiments, the array substrate may also include a second repair layer and second repair lines. The repair method may include: connecting the two ends of the weak connection portion of the data line with vias through at least one of one corresponding first segment of the first repair line or one corresponding second segment of the second repair line.

If projection of the weak connection portion of the data line on the substrate falls within projection of one first segment of the first repair line on the substrate, the two ends of the weak connection portion of the data line are electrically connected by welding the one first segment of the first repair line with the two ends of the weak connection portion of the data line with two vias.

Alternatively, if projection of the weak connection portion of the data line on the substrate falls within projection of one second segment of the second repair line on the substrate, the two ends of the weak connection portion of the data line are electrically connected by welding the one second segment of the second repair line with the two ends of the weak connection portion of the data line with two vias.

Alternatively, if projection of the weak connection portion of the data line on the substrate falls within an overlapping region between projection of one first segment of the first repair line on the substrate and projection of one second segment of the second repair line on the substrate, the two ends of the weak connection portion of the data line are electrically connected by welding the one second segment of the second repair line with the two ends of the weak connection portion of the data line with two vias, or by welding the one second segment of the second repair line with the two ends of the weak connection portion of the data line with two vias.

Other embodiments and implementations can become apparent in view of the following descriptions and drawings.

### BRIEF DESCRIPTION OF THE DRAWINGS

To more clearly illustrate some of the embodiments of the disclosure, the following is a brief description of the drawings. The drawings are only illustrative of some embodiments, and for those of ordinary skill in the art, other drawings of other embodiments can become apparent based on these drawings.

FIG. 1 is a partial view of the structure of an array substrate according to one embodiment of the present disclosure;

FIG. 2 is a partial top view of the structure of the pixel electrode and the first repair line in the array substrate as shown in FIG. 1;

FIG. 3 is a partial cross-section view of the array substrate at position AB as shown in FIG. 1;

FIG. 4 is a partial cross-section view of the array substrate at position CD as shown in FIG. 1;

FIG. 5 is a partial cross-section view of the array substrate at position EF as shown in FIG. 1;

FIG. 6 is a partial view of the structure of an array substrate according to another embodiment of the present disclosure;

FIG. 7 is a partial top view of the common electrode and the second repair line in the array substrate as shown in FIG. 6;

FIG. 8 is a partial top view of the pixel electrode and the first repair line in the array substrate as shown in FIG. 6;

FIG. 9 is a partial cross-section view of the array substrate at position AB as shown in FIG. 6;

FIG. 10 is a partial cross-section view of the array substrate at position CD as shown in FIG. 6.

FIG. 11 is a partial top view of an array substrate where an open portion of a data line is reconnected according to a first embodiment of the repair method.

### DETAILED DESCRIPTION

In the following, with reference to the drawings of various embodiments disclosed herein, the technical solutions of the embodiments of the disclosure will be described in a clear and fully understandable way. It is obvious that the described embodiments are merely a portion but not all of the embodiments of the disclosure. Based on the described embodiments of the disclosure, those ordinarily skilled in the art can obtain other embodiment(s), which come(s) within the scope sought for protection by the disclosure.

It should be noted that throughout the disclosure same or similar reference numerals denote the same or similar components or components that have same or similar functionality.

In an advanced super dimension switch (ADS) display apparatus, a fringe electrical field can be formed through electrodes between pixels within the same plane. Liquid crystal molecules between the electrodes and directly over the electrodes can rotate in the direction of the plane, that is, in a direction parallel to the substrate. As a result, the viewing angel can be increased, and the light-emitting efficiency can be improved.

A conventional array substrate of an ADS display apparatus typically includes: a first transparent electrode layer, a gate layer, a gate insulating layer, a source-drain electrode layer, a second insulating layer, and a second transparent electrode layer of the pixel electrode.

The transparent electrode layer can comprise indium-tin oxide (ITO). The first transparent electrode layer is usually a common electrode layer. The second transparent electrode layer is usually the pixel electrode layer. The gate line and the common electrode line are usually formed in the gate layer. The data line is usually formed in the source-drain electrode layer. As such, the array substrate comprising thin film transistors can be formed.

If there is a data line failure, a repair process may be employed, such as laser cutting, laser chemical vapor deposition (Laser CVD), laser welding, etc. For data line open circuit failures, in most cases a laser CVD equipment is needed to bridge and connect the open portions of the data line with tungsten powder, and the surrounding area of the bridge needs to be processed. For example, laser cutting or scraping of the second transparent electrode layer may be employed.

When repairing data line open circuits employing the conventional repair process, such as bridging with tungsten powder, laser cutting, or scraping, the second transparent electrode layer can be easily damaged, causing decreased display quality or display abnormalities of peripheral pixels.

In order to address these above issues, the present disclosure provides an array substrate. The array substrate comprises a first metal layer including a signal line; a first repair layer; and a first insulating layer. The first insulating layer is disposed between, and provides insulation between, the first metal layer and the first repair layer, and it is configured to be penetrable to allow the first repair layer to electrically connect the signal line to thereby repair connection weakness of the signal line.

In some embodiments, the first repair layer comprises a first repair line, which is disposed over and along the signal line and is configured to be able to electrically connect two ends of a weak connection portion of the signal line through vias penetrating the first insulating layer.

In some embodiment as illustrated below, the signal line can be data lines.

### Embodiment 1

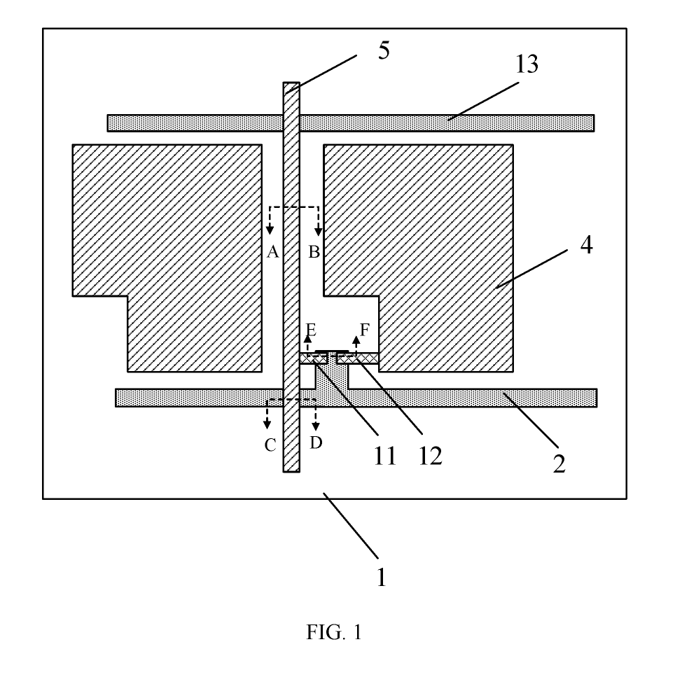

With reference to FIGS. 1-3, the disclosure provides an array substrate, comprising a second metal layer, a first metal layer, and a pixel electrode layer, which are sequentially disposed over a substrate 1. The first metal layer comprises data lines 3; the second metal layer comprises gate lines 2; and the pixel electrode layer comprises pixel electrodes 4.

First repair lines 5 are also disposed in the pixel electrode layer, and the vertical projection of the first repair lines 5 on the substrate 1 falls within the vertical projection of the data lines 3 on the substrate. The first repair lines 5 are configured to connect the two ends of the data lines 3 that are disconnected with vias when the vertical projection of the area where the data line 3 is disconnected falls within the vertical projection of the first repair line 5 in the longitudinal direction.

It should be noted that when only forming the first repair lines 5 over the pixel electrode layer, each of the first repair lines 5 can be an integral wire, as shown in FIG. 1. Because the first repair lines 5 are only formed in the pixel electrode layer, the fabrication process of this structure is relatively simple, but short circuits with a pixel electrode layer can easily occur at the time of repairing. Each of the first repair lines 5 can be divided into different segments according to different situations. However, because the first repair lines 5 are only formed in the pixel electrode layer, if each of the first repair lines 5 is divided into different segments, it is possible that there are no segments of the first repair lines 5 arranged at the disconnected area of the data line 3.

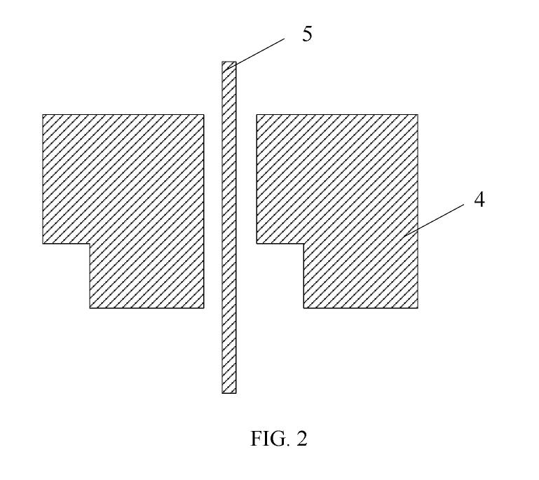

FIG. 2 is a partial top view of the structure of the pixel electrodes 4 and the first repair lines 5 in the pixel electrode layer of the array substrate as shown in FIG. 1.

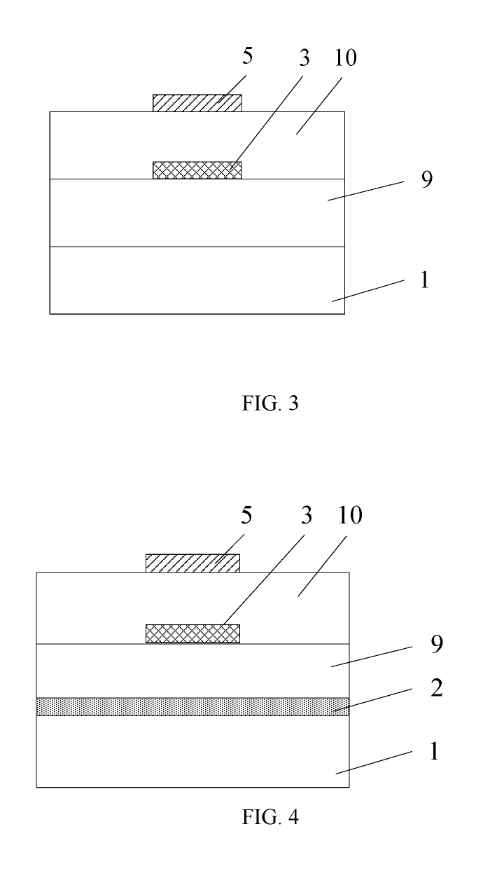

FIG. 3 is a partial cross-sectional view of FIG. 1 at position AB, which illustrates a substrate 1, a first insulating layer 9, a data line 3, a second insulating layer 10, and a first repair line 5, wherein position of the first repair line 5 and position of the data line 3 correspond with each other.

FIG. 4 is a partial cross-sectional view of FIG. 1 at position CD, illustrating a substrate 1, a gate line 2, a first insulating layer 9, a data line 3, a second insulating layer 10 and a first repair line 5, wherein position of the first repair line 5 and position of the data line 3 correspond to each other.

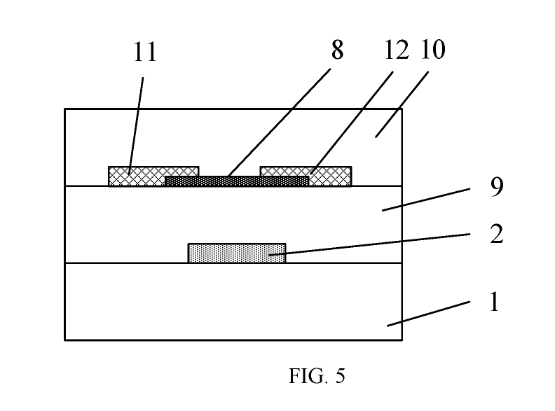

The array substrate further comprises common electrode lines 13 and thin film transistor structures, as shown in FIG. 5, which is a partial cross sectional view of FIG. 1 at position EF. The thin film transistor (TFT) structure comprises a substrate 1, a gate line 2 (i.e. gate electrode, which is part of the gate line 2), a first insulating layer 9, an active layer 8, a source electrode 11, a drain electrode 12 and a second insulating layer 10.

The beneficial effects of this embodiment are as follows: by configuring first repair lines 5 corresponding to data lines 3 in the pixel electrode layer, when open circuit occurs on a data line 3, the first repair line 5 and the two ends of the disconnected data line 3 can be connected together by welding, such that the disconnected data lines 3 can be fixed without influencing the pixel electrodes 4 in peripheral pixels.

### Embodiment 2

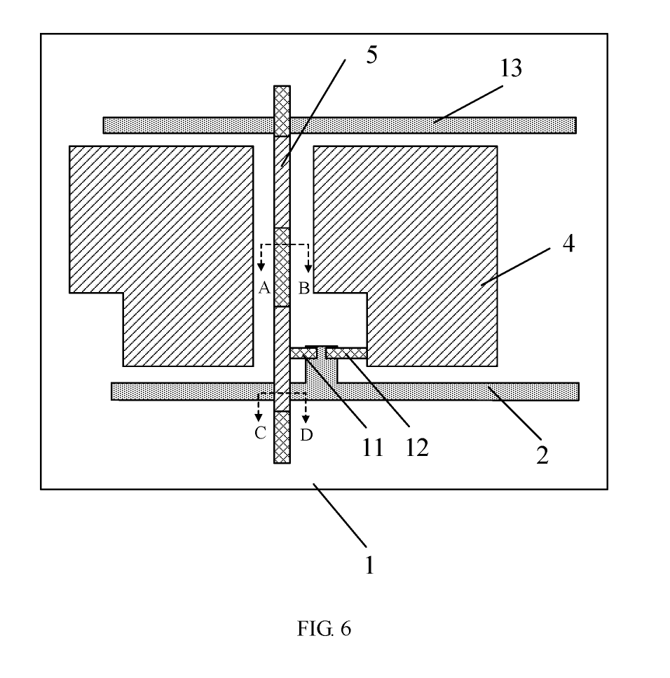

Embodiment 2 is shown in FIGS. 6-8. In this embodiment, an array substrate comprises a second metal layer, a first metal layer, and a pixel electrode layer, sequentially formed over a substrate 1. The first metal layer comprises data lines 3; the second metal layer comprises gate lines 2; and the pixel electrode layer comprises pixel electrodes 4.

The pixel electrode layer further comprises first repair lines 5, and the vertical projection of the first repair lines 5 on the substrate 1 falls within the vertical projection of the data lines 3 on the substrate 1, the first repair lines 5 are configured to connect the two ends of the disconnected data line 3 with vias when the vertical projection of the area of the disconnected data lines 3 falls within the vertical projection of the first repair lines 5 on the substrate 1 in the longitudinal direction.

The array substrate further comprises a common electrode layer, disposed between the substrate 1 and the second metal layer. The common electrode layer comprises common electrodes 6 and second repair lines 7. The vertical projection of the second repair lines 7 on the substrate 1 falls within the vertical projection of the data lines 3 on the substrate 1; the common electrodes 6 and the second repair lines 7 are insulated from each other. Each of the second repair lines 7 can be an integral wire, and can have a structure similar to that of the first repair lines 5 as shown in FIG. 1. The description is not repeated herein.

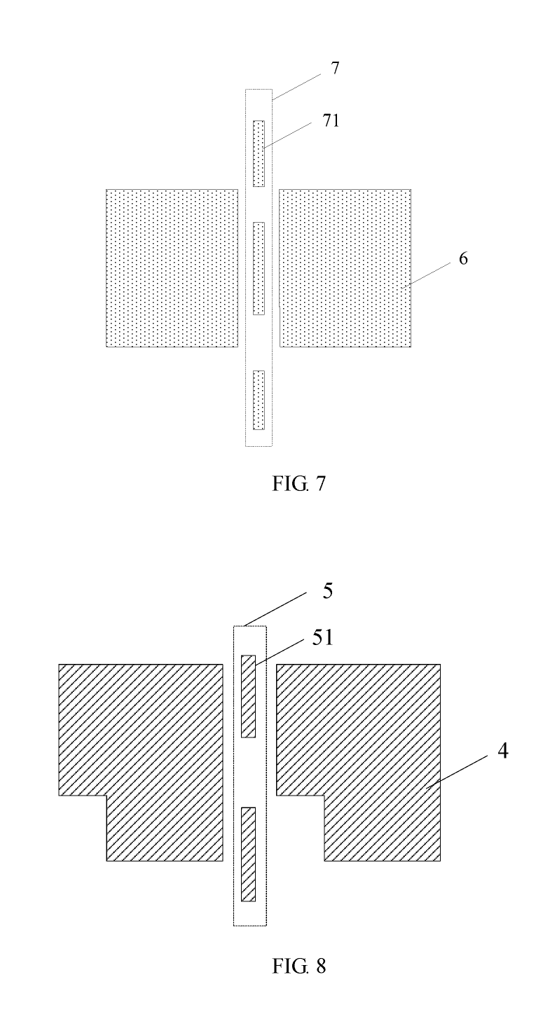

Because forming relatively long repair lines has a high requirement for the manufacturing process, and open circuits are easy to occur on relatively long repair lines, in some embodiments as shown in FIG. 7, a second repair line 7 can comprise a plurality of segments 71, wherein the segments 71 and the gate lines 2 are insulated from each other, the segments 71 are configured to connect the two ends of the disconnected data lines 3 with vias when the vertical projection of the area of the disconnected data line 3 on the substrate 1 falls within the vertical projection of the second repair line segments 71 on the substrate 1 in the longitudinal direction, or it is configured to connect the ends of the disconnected data line 3 with vias when the vertical projection of the ends of the disconnected data line 3 on the substrate 1 falls within the vertical projection of the second repair line segments 71 on the substrate 1 in the longitudinal direction.

It is noted that the second repair line 7 that comprises a plurality of second repair line segments 71 can be directly combined with the structure as shown in FIG. 1, i.e., the first repair lines 5 can each be an integral wire, and the second repair lines 7 each comprises a plurality of segments 71.

However, in order to avoid short circuit at the time of repairing, preferably, as shown in FIG. 8, each of the first repair lines 5 can also comprise a plurality of first repair line segments 51, the vertical projections of each first repair line segment 51 and of each second repair line segment 71 corresponding to the same data line 3 on the substrate 1 are staggered and partially overlapped only at the ends. The first repair line segments 51 are configured to connect two ends of an open portion of a data line 3 with vias if the vertical projection of the open portion of the data line 3 on the substrate 1 falls within the vertical projection of one first repair line segment 51 on the substrate 1 in the longitudinal direction.

FIG. 7 is a partial top view of the common electrodes 6 and the second repair line 7 in the common electrode layer, wherein the second repair line 7 comprises a plurality of the second repair line segments 71.

FIG. 8 is a partial top view of the pixel electrodes 4 and the first repair lines 5 in the pixel electrode layer, wherein the first repair line 5 comprises a plurality of the first repair line segments 51.

It should be noted that the second repair line segments 71 and the common electrode lines 13 should be insulated from each other.

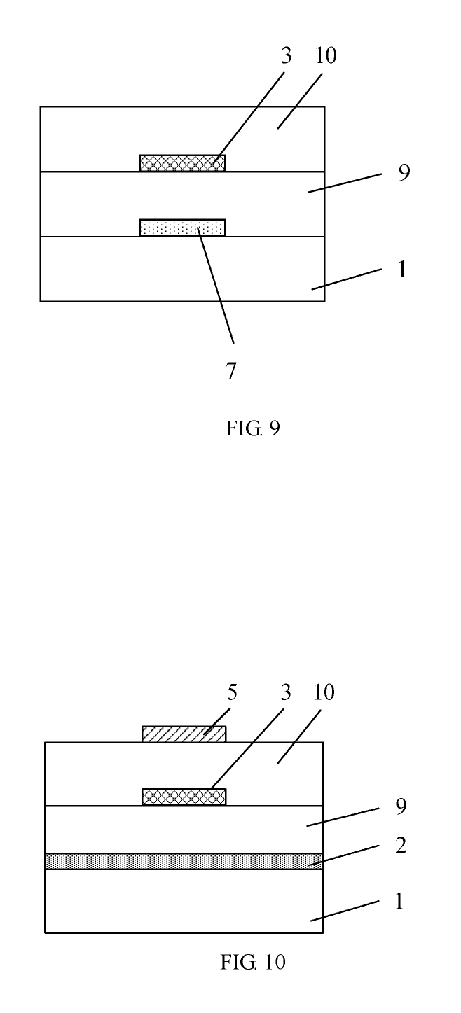

FIG. 9 is a partial cross-sectional view of FIG. 6 at position AB, wherein the array substrate comprises a substrate 1, a second repair line 7, a first insulating layer 9, a data line 3 and a second insulating layer 10, wherein the position of the second repair line 7 and the position of the data line 3 correspond to each other.

FIG. 10 is a partial cross-sectional view of the FIG. 6 at position CD, wherein the array substrate comprises a substrate 1, a gate line 2, a first insulating layer 9, a data line 3, a second insulating layer 10, and a first repair line 5, wherein the position of the first repair line 5 and the position of the data line 3 correspond to each other. The array substrate as shown in FIG. 6 has the same thin film transistor structure as the array substrate as shown in FIG. 1, which is shown in FIG. 5, and will not be repeated herein.

The beneficial effects of embodiments of the present disclosure are as follows:

By arranging repair lines corresponding to data lines 3, and arranging first repair lines 5 corresponding to data lines 3, when open circuit occurs on a data line 3, the first repair line 5 and the two ends of the corresponding disconnected data line 3 can be connected together via welding directly without influencing the pixel electrode 4 in peripheral pixels.

Furthermore, first repair lines 5 having segments 51 and second repair line 7 having segments 71 are configured such that each of the segments 51 of each first repair line 5 and each of the segments 71 of each second repair line 7 are staggered and partially overlapped at the ends of each first repair line segment 51 and each second repair line segment 71. When open circuit occurs on a data line 3, the first repair line segments 51 and the second repair line segments 71 and the two ends of the corresponding disconnected data line 3 can be connected together by welding directly so as to repair the disconnected data line 3 without influencing the pixel electrodes 4 in peripheral pixels. Configuration of first repair lines 5 and second repair lines 7 is flexible, and it is not influenced by the configuration of wires such as gate lines 2 and common electrode lines 13.

In another aspect, the present disclosure provides a display panel, comprising the array substrate according to the above-described embodiments. Furthermore, a display apparatus is provided, which comprises the display panel as described above.

In yet another aspect, the present disclosure provides a method for repairing an array substrate according to Embodiment 1, comprising the following steps:

If the vertical projection of an open portion of a data line on the substrate falls within the vertical projection of a first repair line on the substrate in the longitudinal direction, the two ends of the open portion of the data line can be re-connected with the first repair line with vias.

The beneficial effects of the embodiments of the present disclosure are as follows: by forming repair lines corresponding to data lines over the pixel electrode layer, when open circuit occurs on a data line, the repair line and the two ends of the corresponding disconnected data line can be connected together by welding directly to repair the disconnected data line without influencing the pixel electrodes in peripheral pixels.

The present disclosure further provides a method for repairing an array substrate according to Embodiment 2, comprising the following steps.

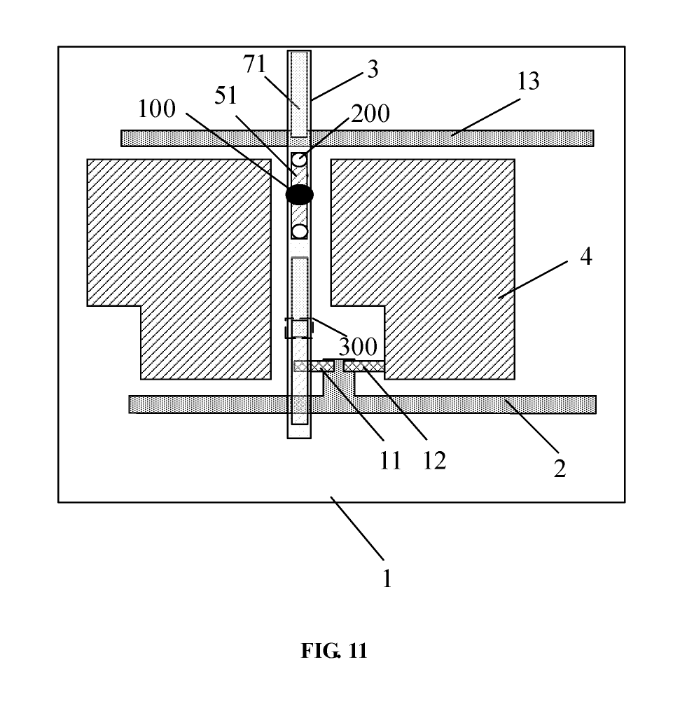

As illustrated in FIG. 11, if the vertical projection of an open portion 100 of a data line on the substrate falls within the vertical projection of a segment 51 of a first repair line on the substrate in the longitudinal direction, the two ends of the open portion 100 of the data line can be re-connected with the segment 51 of the first repair line with two vias 200, wherein the two vias 200 can be configured on the segment 51 of the first repair line, at positions such that the vertical projection of the two vias 200 on the substrate respectively fall on two sides of the vertical projection of the open portion 100 of the data line on the substrate.

Alternatively, if the vertical projection of an open portion 100 of a data line on the substrate falls within the vertical projection of a segment 71 of a second repair line on the substrate in the longitudinal direction, the two ends of the open portion 100 of the data line can be re-connected with the segment 71 of the second repair line with two vias 200, wherein the two vias 200 can be configured on the segment 71 of the second repair line, at positions such that the vertical projection of the two vias 200 on the substrate respectively fall on two sides of the vertical projection of the open portion 100 of the data line on the substrate (figure not shown).

Alternatively, it is possible that the vertical projection of an open portion 100 of a data line on the substrate falls within an overlapping region 300 between the vertical projection of a segment 51 of a first repair line on the substrate and the vertical projection of a segment 71 of a second repair line on the substrate. Under this situation, the two ends of the open portion 100 of the data line can be re-connected either with the segment 51 of the first repair line with two vias 200, or with the segment 71 of the second repair line with two vias 200. In either of these two solutions, the two vias 200 can be configured at positions such that the vertical projection of the two vias 200 on the substrate respectively fall on two sides of the vertical projection of the open portion 100 of the data line on the substrate (figure not shown).

The beneficial effects of the embodiments of the present disclosure are as follows: by configuring segmented first repair lines and segmented second repair lines over the common electrode layer and the pixel electrode layer respectively, and by configuring that each of the segments of the first repair line and each of the segments of the second repair line are staggered and partially overlapped at the ends, if open circuit occurs on a data line, the first repair line segments and the second repair line segments can be connected with the two ends of the disconnected data line via welding directly to repair the disconnected data line without influencing the pixel electrodes in peripheral pixels.

Although specific embodiments have been described above in detail, the description is merely for purposes of illustration. It should be appreciated, therefore, that many aspects described above are not intended as required or essential elements unless explicitly stated otherwise.

Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

1. An array substrate, comprising:
a first metal layer, including a signal line;
a first repair layer; and
a first insulating layer disposed between, and provides insulation between, the first metal layer and the first repair layer;
wherein:
the first insulating layer is configured to be penetrable to allow the first repair layer to electrically connect the signal line to thereby repair connection weakness of the signal line.

2. The array substrate of claim 1, wherein the first repair layer comprises a first repair line, disposed over and along the signal line, and configured to be able to electrically connect two ends of a weak connection portion of the signal line through vias penetrating the first insulating layer.

3. The array substrate of claim 2, further comprising a substrate, wherein projection of the first repair line on the substrate overlaps with projection of the signal line on the substrate in a longitudinal direction.

4. The array substrate of claim 3, wherein the signal line in the first metal layer comprises a data line.

5. The array substrate of claim 4, wherein the first repair line is an integral wire.

6. The array substrate of claim 4, wherein the first repair line comprises a plurality of first segments, electrically disconnected from one another.

7. The array substrate of claim 6, further comprising: a second repair layer including a second repair line, wherein:
the second repair line is insulated from, and disposed over and along, the data line;
projection of the second repair line on the substrate overlaps with projection of the data line on the substrate in a longitudinal direction; and
the second repair line comprises a plurality of second segments, electrically disconnected from one another;
wherein:
the plurality of first segments of the first repair line and the plurality of second segments of the second repair line are configured such that at least one of one corresponding first segment of the first repair line or one corresponding second segment of the second repair line is able to electrically connect the two ends of the weak connection portion of the data line through one or more vias.

8. The array substrate of claim 7, wherein each one of the plurality of first segments of the first repair line is staggered with, and partially overlapped at ends with, one of the plurality of second segments of the second repair line.

9. The array substrate of claim 7, wherein one of the first repair layer and the second repair layer is a pixel electrode layer, and another thereof is a common electrode layer.

10. The array substrate of claim 9, wherein the first repair layer is a pixel electrode layer, and the second repair layer is a common electrode layer, wherein:
the pixel electrode layer comprises a plurality of pixel electrodes, insulated from the first repair line;
the common electrode layer comprises a plurality of common electrodes, insulated from the second repair line.

11. The array substrate of claim 10, further comprising a second metal layer, the second metal layer comprising a plurality of gate lines, wherein:
the second repair layer, the second metal layer, the first metal layer, and the first repair layer are sequentially disposed on the substrate; and
the plurality of gate lines in the second metal layer are insulated from the second repair line in the second repair layer.

12. The array substrate of claim 11, further comprising a second insulating layer, wherein the second insulating layer is disposed between, and configured to insulate, the second metal layer and the first metal layer.

13. (canceled)

14. A display apparatus, comprising a display panel, wherein the display panel comprises the array substrate according to claim 1.

15. A method for repairing an array substrate according to claim 1, the method comprising a step of connecting the two ends of the weak connection portion of the signal line with vias through the first repair line.

16. The method of claim 15, wherein the step of connecting the two ends of the weak connection portion of the signal line with vias through the first repair line is performed by welding the first repair line with the two ends of the weak connection portion of the signal line through vias.

17. The method of claim 15, wherein:
the first repair line comprises a plurality of first segments, electrically disconnected from one another; and
the step of connecting the two ends of the weak connection portion of the signal line with vias through the first repair line is performed by welding one of the plurality of first segments of the first repair line with the two ends of the weak connection portion of the signal line through vias.

18. A method for repairing an array substrate according to claim 7, the method comprising: connecting the two ends of the weak connection portion of the data line with vias through at least one of one corresponding first segment of the first repair line or one corresponding second segment of the second repair line.

19. The method of claim 18, wherein: if projection of the weak connection portion of the data line on the substrate falls within projection of one first segment of the first repair line on the substrate, the two ends of the weak connection portion of the data line are electrically connected by welding the one first segment of the first repair line with the two ends of the weak connection portion of the data line with two vias.

20. The method of claim 18, wherein: if projection of the weak connection portion of the data line on the substrate falls within projection of one second segment of the second repair line on the substrate, the two ends of the weak connection portion of the data line are electrically connected by welding the one second segment of the second repair line with the two ends of the weak connection portion of the data line with two vias.

21. The method of claim 18, wherein: if projection of the weak connection portion of the data line on the substrate falls within an overlapping region between projection of one first segment of the first repair line on the substrate and projection of one second segment of the second repair line on the substrate, the two ends of the weak connection portion of the data line are electrically connected:
by welding the one first segment of the first repair line with the two ends of the weak connection portion of the data line with two vias; or
by welding the one second segment of the second repair line with the two ends of the weak connection portion of the data line with two vias.
